(19) United States
(12) Patent Application Publication
(10) Pub. No.: US 2018/0151770 A1
(43) Pub. Date: May 31, 2018

(54) PHOTOVOLTAIC CELL STRUCTURE AND METHOD TO PRODUCE THE SAME

(71) Applicant: INSTYTUT FIZYKI PAN, Warszawa (PL)

(72) Inventors: Sylwia GIERALTOWSKA, Warszawa (PL); Marek GODLEWSKI, Warszawa (PL); Rafal PIETRUSZKA, Wilczyce (PL); Lukasz WACHNICKI, Warszawa (PL); Bartlomiej WITKOWSKI, Warszawa (PL)

(21) Appl. No.: 15/572,416

(22) PCT Filed: May 6, 2016
(86) PCT No.: PCT/PL2016/050016

§ 371 Date: Nov. 7, 2017

(30) Foreign Application Priority Data
May 8, 2015 (PL) P.412250

(51) Int. Cl. H01L 31/074; H01L 31/0224; H01L 31/028; H01L 31/0296; H01L 31/032; H01L 31/0336; H01L 31/0352; H01L 31/18

(52) U.S. Cl. CPC H01L 31/074; H01L 31/022483; H01L 31/028; H01L 31/0296; H01L 31/1884; H01L 31/0336; H01L 31/035227; H01L 31/1836; H01L 31/032

(57) ABSTRACT

The object of the present invention is a photovoltaic cell structure, comprising a p-type semiconductor substrate with a bottom electric contact, upon which a layer comprising ZnO nano structures is made, covered with a Zn Mg O layer and with a transparent conductive layer, preferably ZnO:Al layer, with an electric contact, characterized in that the active layer is a Si/ZnO/ZnMgO junction, the layer of ZnO nano structures of the height of 100 nm up to 2000 nm being covered with the ZnMgO layer from 1 nm to 2000 nm thick, and the method to produce the same.

This invention relates to a photovoltaic cell structure and method to produce the same. Such structures can be used as an electric energy source since they generate voltage on illumination.

There are descriptions of various kinds of photovoltaic structures in scientific and patent literature. The most popular ones comprise silicon photovoltaic cells PV that constitute almost 90% of the photovoltaic market. Currently, there are commercially available PV panels comprising monocrystalline, polycrystalline, and amorphous thin layer silicon cells. Although significant progress in PV cells/structures based both on monocrystalline and polycrystalline silicon has been observed, the manufacturing technology is still too expensive and in the majority of cases it is simply uneconomical. The remaining 10% of the photovoltaic market consists of photovoltaic cells based on thin-layer materials such as cadmium telluride (CdTe), cadmium sulphide (CdS), copper-indium-gallium-selenide alloys (CIGS), and multi-junction cells using A^{III}B^{V} materials. The drawback of thin-layer CdTe—CdS cells is their high price (especially the costs of Tellurium that is also to scarce to meet the photovoltaics market demand) as well as their negative environmental impact due to the application of cadmium. Another aspect limiting the applicability of CdTe based technology are the problems connected with the performance of ohmic contacts both for p-type CdTe and n-type CdS. These impediments make CdTe and CdS difficult materials for photovoltaics. In case of cells based on copper-indium-gallium-selenide alloy (CIGS), the problem is similar since the most commonly used partner for p-type conductivity of CIGS is CdS. Cells containing multiple layers of various materials, so called multi-junction cells made by Molecular Beam Epitaxy (MBE) and by Chemical Vapor Deposition (CVD) are also known. Structures of such cells are generally built of three layers. The lower layer is a base layer of germanium (Ge), the middle layer is a InGaAs multilayer, and the upper layer is also multilayer of InGaP. The efficiency of the triple-junction cells is in fact the highest (of the magnitude of 40% in laboratory conditions), but their manufacturing cost is very high which makes their mass production impossible. Besides, the method of obtaining time stable tunnel layers is very complex, and those high efficiencies are used only under concentrated lightning, but then the problem of such cells getting hot appears. From a publication by R. Pietruszka, G. Luka, B. S. Witkowski, K. Kopalko, E. Zielony, P. Bieganski, E. Placzek-Popko, M. Godlewski, “Electrical and photovoltaic properties of ZnO/Si heterostructures with ZnO films grown by atomic layer deposition”, Thin Solid Films, doi: 10.1016/j.tsf.2013.10.110, a photovoltaic cell structure is knows, being created by means of the Atomic Layer Deposition (ALD) technology. The structure is a triple-layer structure in the arrangement of: p-type semiconductor/n-type semiconductor/transparent electrode. The substrate in this structure is a p-type semiconductor that is the first layer, the second layer is a (n-type) layer of zinc oxide, and the third layer is a layer of zinc oxide doped with aluminum. The cost to produce such structure is relatively low as compared to that of commercially produced structures, and the efficiency of the cell made of such structures reaches 6%. Polish Patent Application PL407336 discloses a cell consisting of a substrate in the form of p-type silicon, covered with a layer of ZnO nanorods that are in turn covered with a layer ZnO. The function of the upper layer covering the nanorods is the extend the Si/ZnO junction that constitutes the active element of the cell. In the method according to the present invention, ZnO nanostructures on the silicon substrate are covered with a ZnMgO layer that, unlike the one according to the application referred to above, is not designed to extend the junction area, but to improve the transparency of the upper cell layers that do not actively participate in light absorption. The above solution resulted in that the achieved efficiency is 1.5% higher and is 14%. In the theoretical work by K. E. Knutsen, R. Schifano, E. S. Marstein, B. G. Svensson, A. Yu. Kuznetov, “Prediction of high Efficiency ZnMgO/Si solar cells suppressing carrier recombination by conduction band engineering”, Physica Status Solodi A, doi: 10.1002/pssa.201228527, a photovoltaic ZnMgO/Si structure is contemplated. A detailed analysis of the influence of the magnesium doping to the photovoltaic response of a ZnMgO/Si cell has been carried out in that work. Theoretical computations indicate the possibility to move the conductivity level of ZnMgO away from the silicon valence level. Therefore, the influence of recombination centers is strongly reduced. This effect leads to the increase of obtained efficiencies in such photovoltaic structures. A photovoltaic cell with extended working spectral range enabling absorbing near-UV range with relatively cheap production technology and high efficiency is still being sought. The object of the invention is to develop a photovoltaic structure of increased efficiency and relatively cheap production method of such structure.

The first object of the present invention is a photovoltaic structure comprising a p-type semiconductor substrate with bottom electric contact, on which there is a layer comprising ZnO nanorods, and then a ZnMgO layer with a transparent conductive layer on it, preferably a ZnO:Al layer with an electric contact. In that structure, the layer comprising ZnO and ZnMgO, placed between the substrate, preferably silicon one, and the transparent conductive layer, preferably ZnO:Al layer, is a layer of ZnO nanostructures of the height ranging from 10 nm up to 2000 nm, covered with a ZnMgO layer from 1 nm up to 2000 nm thick. Preferably, the nucleating layer for growing ZnO nanostructures is a layer of gold, silver or ZnO layer, or nanoparticles of these materials. Equally preferably, the transparent conducting layer is made of ITO (Indium Tin Oxide) or SnO₂. ZnO nanostructures can have the form of nanorods.

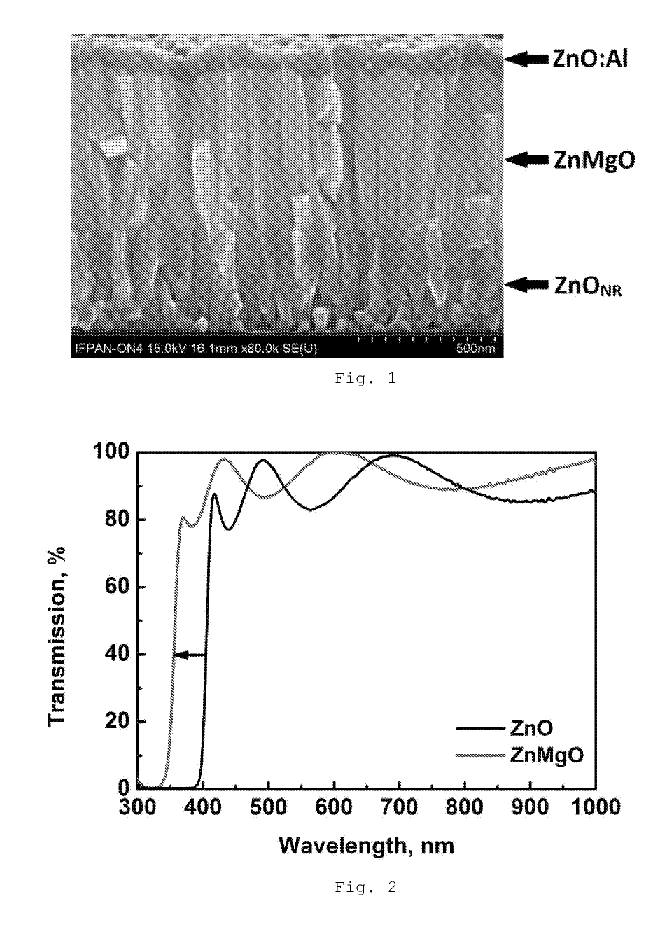

The second object of the present invention is the method to produce a photovoltaic structure, characterized in that a layer comprising ZnO in the form of nanorods covered with a ZnMgO layer is made upon a substrate, preferably of silicon, with prepared bottom electric contact. In order to produce the ZnO nanostructures layer, the substrate is first covered with the nucleating layer. The nucleating layer can be a layer of gold, silver or nanoparticles thereof deposited by means of sputtering process or the ZnO layer, or ZnO nanoparticles deposited from a solution or obtained by annealing zinc salt (e.g. zinc acetate) deposited from solution or deposited in at least 1 ALD cycle, using diethylzinc, dimethylzinc or zinc chloride as zinc precursor, and water, ozone or oxygen plasma as oxygen precursor. Having deposited the nucleating layer, the substrate is placed in a solution with pH of 6.5 to 12, containing a solvent, at least one oxygen precursor and at least one zinc precursor, heated to the temperature of 30-95° C. and kept at this temperature for at least 1 second. Zinc concentration in the solution should be higher than 0.001 M/dm³, and lower than 1 M/dm³. It is preferred when the oxygen precursor in the reaction mixture is water, and the zinc precursor is zinc acetate. The pH of the solution is adjusted by precipitation with a metal hydroxide solution (e.g. NaOH, KOH). After the process is completed, contamination is removed from crystalline ZnO nanorodes, preferably by annealing for at least 1 second in the temperature of 100°, after which the ZnO nanorodes are covered with a ZnMgO layer in an ALD process. It is preferred that the ZnMgO layer be deposited in at least 10 ALD cycles, using diethylzinc, dimethylzinc or zinc chloride as zinc precursor, bis(cyclopentadienyl)magnesium or bis(methylcyclopentadienyl)magnesium as magnesium precursor, and water, ozone or oxygen plasma as oxygen precursor. Next, the layer of ZnO nanostructures covered with the ZnMgO layer is covered with the transparent ZnO:Al electrode layer, and top electric contact is made. It is preferred that the transparent ZnO layer doped with aluminum be deposited in at least 100 ALD cycles, using diethylzinc, dimethylzinc or zinc chloride as zinc precursor, water, ozone or oxygen plasma as oxygen precursor, and trimethylaluminum as aluminum precursor. The solution according to the present invention uses the ZnMgO layer that is deposited on ZnO nanorodes. According to the invention, the junction is created by joining n-ZnO and p-Si semiconductor nanostructures together. The present invention utilizes the new effects of magnesium doping influence upon the ZnO layer. First of all, the influence of magnesium doping upon the resistivity and growth mode of the layer is used. By selecting appropriate conditions between Zn, O, and Mg atoms concentration, the resistivity or the ZnO layer changes within the 10⁻² to 10² Ωcm range. Also, column growth mode of ZnMgO layer is observed on nanorodes (FIG. 1). Columns of ZnMgO grow epitaxially on ZnO nanorodes replicating their high crystallographic quality. Due to that phenomenon, monocrystalline ZnMgO columns are grown on ZnO_{NR}, effectively separating the carriers and providing them to the upper electrode. Another effect of magnesium doping influence upon ZnO layer taken advantage of is the extension of the spectral range of the ZnMgO/ZnO_{NR}/Si photovoltaic cell operation. This effect enables the structure absorbing near UV area that translates into the increased number of photo-generated electric current carriers. FIG. 2 illustrates the influence of magnesium doping upon increasing ZnO layer transparency. The effect allows photons from near UV area reach the junction area and actively participate in creation of electron-hole pairs. The obtained structure generates electrical voltage when subjected to visible, infrared, and near-UV light spectrum. The technology to produce the photovoltaic structure according to the present invention is cheap and simple, and the structure is a reusable one.

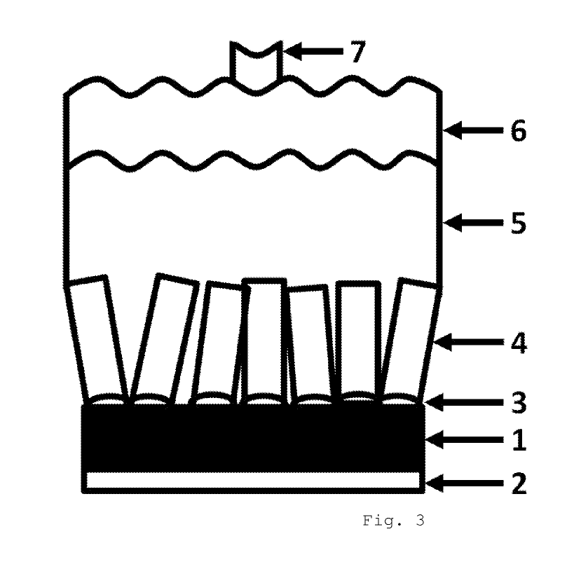

The invention will be now explained in a more detailed way by means of the Al/ZnO:Al/ZnMgO/ZnO_{NR}/Si/Al photovoltaic structure embodiment and the drawings, where FIG. 1 illustrates the column growth mode of ZnMgO layer upon ZnO nanorodes, FIG. 2 illustrates the extension of spectral transparency of the ZnO layer doped with magnesium, and FIG. 3 illustrate the structure according to the invention. Example 1 To carry out the example structure, commercially available p-type silicon substrate with electrical resistivity of 2.3 Ωcm and dimensions of 1.5×1.5 cm was used. First, the substrate was subjected to cleaning that was carried out in a ultrasonic washer. The substrate was rinsed in 3 steps of 30 seconds each, in isopropanol, acetone, and deionized water, respectively. Aluminum film 2, constituting the bottom electric contact, was deposited with cathode sputtering upon the cleaned substrate 1. In the second step, the creation of the active ZnO layer in the form of ZnO nanorods 4 covered with thin film of ZnO 5 upon the cleaned substrate was commenced. For that purpose, first, silver nanoparticles constituting the nucleation layer 3 for hydrothermal growth of nanorodes were deposited upon the upper surface of the substrate 1 also by cathode sputtering. Next, the substrate with the nuclei was placed in 100 ml of a reaction mixture containing 1 g dissolved zinc acetate and brought to the pH equal 8 by precipitation by 1-mol sodium hydroxide solution. The mixture with the substrate was heated to the temperature of 50° C. and the growth of nanorodes to the height of 650 nm was continued in that temperature for 2 minutes. After the growth completed, the substrate 1 with the crystallized nanorods 4 was rinsed in isopropanol to remove possible impurities, and deposition of ZnO layer 5 upon them started. For that purpose, the substrate was placed in an ALD reactor where it was annealed for 2 minutes in 200° C. After annealing, the reactor chamber was cooled down to 160° C., and the ZnO nanorodes were thoroughly covered with a ZnMgO layer ca. 200 nm thick in 1000 ALD cycles at that temperature. The ZnMgO layer 5 was deposited with diethylzinc as zinc precursor, water as oxygen precursor, and bis(methylcyclopentadienyl)magnesium as magnesium precursor. Further on, at the same temperature and without removing the substrate with the deposited ZnO nanostructures covered with ZnMgO layer from the ALD reactor, the transparent electrode layer 6 in the form of ZnO:Al and thickness of 300 nm being the upper transparent electrode 6 was deposited. The electrode layer 6 was deposited with dietylzinc as zinc precursor, water as oxygen precursor, and trimethylaluminum as aluminum precursor. Having deposited electrode layer 6, the point ohmic contact with the ZnO:Al layer 7, made of aluminum, was deposited by cathode sputtering process. Coating the ZnO nanorodes with the ZnMgO layer increased the transparency of the upper part of the cell that does not participate in absorption, which significantly influenced the efficiency of the structure according to the present invention. The obtained structure demonstrated the efficiency of 14% (laboratory measurements made with sunlight simulator).

### EXAMPLE 2

To carry out the second example structure, commercially available p-type silicon substrate with electrical resistivity of 2.3 Ωcm and dimensions of 1.5×1.5 cm was also used. First, the substrate was subjected to cleaning that was carried out in a ultrasonic washer. The substrate was washed for 30 seconds, consecutively in deionized water. Aluminum film 2, constituting the bottom electric contact, was deposited with cathode sputtering upon the cleaned substrate 1. In the second step, the creation of the active ZnO layer in the form of ZnO nanorods 4 covered with thin film of ZnO 5 upon the cleaned substrate was commenced. For that purpose, nanoparticles ZnO being the nucleation layer 3 for hydrothermal growth of nanorodes were deposited upon the upper surface of the substrate 1 in 10 ALD cycles and temperature of 100° C., using water as oxygen precursor and diethylzinc as zinc precursor. Next, the substrate with the nuclei was placed in 110 ml of a reaction mixture containing 2 g dissolved zinc acetate and brought to the pH equal 7.7 by precipitation with 1-mol potassium hydroxide solution. The mixture with the substrate was heated to the temperature of 70° C. and the growth of nanorodes to the height of 1200 nm was continued in that temperature for 2 minutes. After the growth completed, the substrate 1 with the crystallized nanorods 4 was rinsed in isopropanol to remove possible impurities, and deposition of ZnO layer 5 upon them started. For that purpose, the substrate was placed in an ALD reactor where it was annealed for 2 minutes in 200° C. After annealing, the reactor chamber was cooled down to 160° C., and the ZnO nanorodes were thoroughly covered with a ZnMgO layer ca. 1000 nm thick in 4000 ALD cycles at that temperature. The ZnMgO layer 5 was deposited with diethylzinc as zinc precursor, water as oxygen precursor, and bis(methylcyclopentadienyl)magnesium as magnesium precursor. Further on, at the same temperature and without removing the substrate with the deposited ZnO nanostructures covered with ZnMgO layer from the ALD reactor, the transparent electrode layer 6 in the form of ZnO:Al and thickness of 500 nm being the upper transparent electrode 6 was deposited. The electrode layer 6 was deposited with diethylzinc as zinc precursor, water as oxygen precursor, and trimethylaluminum as aluminum precursor. Having deposited electrode layer 6, the point ohmic contact with the ZnO:Al layer 7, made of aluminum, was deposited by cathode sputtering process. The obtained structure demonstrated the efficiency of 5% (laboratory measurements made with sunlight simulator). On application of higher ZnO nanorodes or even thicker ZnMgO layer, the cell efficiency decreases dramatically. For nanorodes higher than 2000 nm and ZnMgO layer thicker than 2000 nm, the cell efficiency is close to 0—the cell stops working.

1. A photovoltaic cell structure, containing a p-type semiconductor substrate with bottom electric contact, with a layer comprising ZnO and ZnMgO covered with a transparent conductive layer, preferably ZnO:Al layer, with an electric contact, characterized in that the active layer is a Si/ZnO/ZnMgO junction, the layer of ZnO nanostructures of the height of 100 nm up to 2000 nm being covered with the ZnMgO layer from 1 nm to 2000 nm thick.

2. The structure according to claim 1, characterized in that the nucleating layer for growing ZnO nanostructures is a layer of gold, silver or ZnO, or nanoparticles of these materials.

3. The method to produce photovoltaic cell, wherein layer containing ZnO and ZnMgO covered with a deposited transparent ZnO:Al layer with an electric contact is deposited on a p-type substrate with a bottom electric contact, characterized in that a layer of ZnO nanostructures in the form on nanorodes covered with a ZnMgO is created upon a substrate, preferably silicon one, wherein in order to create the said layer, the substrate is first covered with a nucleating layer and then the substrate with the nucleating layer is placed in a reacting mixture with pH of 6.5-12, containing a solvent, at least one oxygen precursor and at least one zinc precursor, zinc concentration being from 0.001 M/dm3 to 1 M/dm3, heated up to the temperature of 30-95° C. and maintained at that temperature for at least 1 second, and upon completion of the process, impurities are removed from the crystallized nanostructures, preferably by annealing for at least 1 second in the temperature of ≥100° C., after which the nanostructures are covered with a ZnMgO layer at least 1 nm thick in an ALD process, and so created active layer is covered with a transparent ZnO:Al electrode upon which the upper electric contact is made.

4. The method of claim 3, characterized in that the nucleating layer is deposited on the substrate be means of cathode sputtering of gold, silver, or nanoparticles of those metals.

5. The method of claim 3, characterized in that the nucleating layer is a ZnO layer or ZnO nanoparticles deposited on the substrate from a solution or obtained by annealing zinc salts deposited from a solution, or deposited in at least 1 ALD cycle, the precursor of zinc being diethylzinc, dimethylzinc or zinc chloride, and the precursor of oxygen being water, ozone, or oxygen plasma.

6. The method of claim 3, characterized in that the oxygen precursor in the reaction mixture is water, and the zinc precursor is zinc acetate.

7. The method of claim 3, characterize in that the ZnMgO layer that the active layer nanorodes are covered with is deposited in at least 10 ALD cycles, using diethylzinc, dimethylzinc or zinc chloride as zinc precursor, bis(methylcyclopentadienyl)magnesium as Mg precursor, and water, ozone or oxygen plasma as oxygen precursor.

8. The method of claim 3, characterized in that the transparent ZnO:Al layer is deposited in at least 100 ALD cycles, using diethylzinc, dimethylzinc or zinc chloride as zinc precursor, water, ozone or oxygen plasma as oxygen precursor, and trimethylaluminum as aluminum precursor.
